(19) United States
(12) Patent Application Publication
(10) Pub. No.: US 2026/0015717 A1
(43) Pub. Date: Jan. 15, 2026

(54) METHODS OF FILLING GAP ON SUBSTRATE SURFACE

(71) Applicant: ASM IP Holding B.V., Almere (NL)

(72) Inventors: Hirotsugu Sugiura, Tokyo (JP); Keigo Kurumisawa, Tokyo (JP); Tamal Saha, Tokyo (JP); Yoshiyuki Kikuchi, Tokyo (JP); Alexey Remnev, Kawasaki (JP); Abhudaya Mishra, Chandler, AZ (US)

(21) Appl. No.: 19/261,057

(22) Filed: Jul. 7, 2025

Related U.S. Application Data
(60) Provisional application No. 63/669,314, filed on Jul. 10, 2024.

(51) Int. Cl. C23C 16/26; C23C 16/505; C23C 16/56

(52) U.S. Cl. CPC C23C 16/26; C23C 16/505; C23C 16/56

(57) ABSTRACT

A method of filling a gap on a surface of a substrate is provided. The method may comprise the steps of: (a) placing a substrate on a susceptor within a reaction chamber, the substrate comprising a gap; (b) a deposition step comprising: flowing a carbon precursor into the reaction chamber; wherein a chemical formula of the carbon precursor comprises: a cyclic compound having a cyclic structure comprising C, H, and N; a carbonyl group; and at least one of a methyl group, an ethyl group, a propyl group, a butyl group, an amine group, and/or a hydroxy group; and exposing the carbon precursor to a plasma, wherein the carbon precursor reacts to form a first deposited material; and (c) a treatment step comprising: exposing the first deposited material to a post-deposition treatment to cause the first deposited material to flow within the gap for forming a carbon film.

### CROSS-REFERENCE TO RELATED APPLICATIONS

This application claims priority to U.S. Provisional Patent Application Ser. No. 63/669,314 filed Jul. 10, 2024 and titled METHODS OF FILLING GAP ON SUBSTRATE SURFACE, the disclosure of which is hereby incorporated by reference in its entirety.

### FIELD OF INVENTION

The present disclosure generally relates to methods of forming structures suitable for use in the manufacture of electronic devices. More particularly, examples of the disclosure relate to methods of forming structures including depositing a material layer that may fill a gap on a surface of the structure.

### BACKGROUND OF THE DISCLOSURE

During the manufacture of devices, such as semiconductor devices, it is often desirable to fill gaps on the surface of a substrate. Some techniques to fill gaps include the deposition of a layer of flowable material, such as a flowable carbon material.

Although use of flowable carbon material to fill gaps may work well for some applications, deposition techniques of flowable carbon may exhibit low elastic modulus and low etching resistance. Further, a deposited carbon material may shrink considerably after an annealing process. Accordingly, improved methods of filling gaps on a substrate are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a method of filling a gap on a substrate is provided. The method may comprise the steps of: (a) placing a substrate on a susceptor within a reaction chamber, the substrate comprising a gap; (b) a deposition step comprising: flowing a carbon precursor into the reaction chamber; wherein a chemical formula of the carbon precursor comprises: a cyclic compound having a cyclic structure comprising C, H, and N; a carbonyl group; and at least one of a methyl group, an ethyl group, a propyl group, a butyl group, an amine group, and/or a hydroxy group; and exposing the carbon precursor to a plasma, wherein the carbon precursor reacts to form a first deposited material; and (c) a treatment step comprising: exposing the first deposited material to a post-deposition treatment to cause the first deposited material to flow within the gap for forming a carbon film.

In accordance with further exemplary embodiments of the disclosure, a temperature during the deposition step may be between 30° C. and 700° C.

In accordance with further exemplary embodiments of the disclosure, the method may further comprise providing an inert gas and/or an atomic oxygen-containing gas during the treatment step.

In accordance with further exemplary embodiments of the disclosure, the atomic oxygen-containing gas may comprise one of O₂, O₃, N₂O, NO, NO₂, CO₂, CO, H₂O, CH₃OH, C₂H₅OH, or a combination thereof.

In accordance with further exemplary embodiments of the disclosure, the inert gas may comprise at least one of: He, H₂, N₂, He, Ar, or combinations thereof.

In accordance with further exemplary embodiments of the disclosure, the inert gas may comprise N₂ and the atomic oxygen-containing gas comprises O₂.

In accordance with further exemplary embodiments of the disclosure, the ratio of O₂ may be more than 25% in total gas.

In accordance with further exemplary embodiments of the disclosure, a duration of the post-deposition treatment may be between 1 second and 1,800 seconds.

In accordance with further exemplary embodiments of the disclosure, the post-deposition treatment may comprise annealing the substrate to a temperature of 200° C. to 800° C.

In accordance with further exemplary embodiments of the disclosure, the post-deposition treatment may comprise a plasma treatment.

In accordance with further exemplary embodiments of the disclosure, the post-deposition treatment may comprise a UV curing.

In accordance with further exemplary embodiments of the disclosure, the post-deposition treatment may be conducted in a second reaction chamber.

In accordance with further exemplary embodiments of the disclosure, a power of the plasma may be between 10 W and 3000 W.

In accordance with further exemplary embodiments of the disclosure, a frequency of the plasma may be between 400 kHz and 100 MHz.

In accordance with further exemplary embodiments of the disclosure, the cyclic structure may comprise one of pyrrole, furan, thiophene, phosphole, pyrazole, imidazole, oxazole, isoxazole, thiazole, indole, benzofuran, benzothiophene, isoindole, isobenzofurane, benzophosphole, benzimidazole, benzoxazole, benzothiazole, benzoisoxazole, indazole, benzoisothiazole, benzotriazole, purine, pyridine, phosphinine, pyrimidine, pyrazine, pyridazine, triazine, 1,2,4,5-tetrazine, 1,2,3,4,-tetrazine, 1,2,3,5-tetrazine, hexazine, quinoline, isoquinoline, quinoxaline, quinazoline, cinnoline, pteridine, phthalazine, acridine, 4aH-xanthene, 4aH-thioxanthene, 4aH-phenoxazine, 4a, 10a-dihydro-10H-phenothiazine, carbazole, or a combination thereof.

In accordance with further exemplary embodiments of the disclosure, the carbonyl group may comprise one of Aldehyde, Ketone, Carboxylic acid, Ester, Amide, Enone, Acyl chloride, Acid anhydride, or a combination thereof.

In accordance with further exemplary embodiments of the disclosure, one of the electrodes may be part of the susceptor.

In accordance with further exemplary embodiments of the disclosure, an elastic modulus of the carbon layer may be more than 7 GPa.

### BRIEF DESCRIPTION OF THE DRAWING FIGURES

A more complete understanding of exemplary embodiments of the present disclosure may be derived by referring to the detailed description and claims when considered in connection with the following illustrative figures.

FIG. 1 illustrates a method in accordance with exemplary embodiments of the disclosure.

FIG. 2 illustrates a structure in accordance with exemplary embodiments of the disclosure.

FIG. 3 illustrates a plasma system in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

In this disclosure, “gas” may include material that is a gas at normal temperature and pressure, a vaporized solid and/or a vaporized liquid, and may be constituted by a single gas or a mixture of gases, depending on the context. A gas introduced without passing through a gas supply unit, such as a shower plate, or the like, may be used for, e.g., sealing the reaction space, and may include a seal gas, such as a rare or other inert gas. The term inert gas, carrier gas, and dilution gas refer to a gas that does not take part in a chemical reaction to an appreciable extent and/or a gas that may excite a precursor when plasma power is applied.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

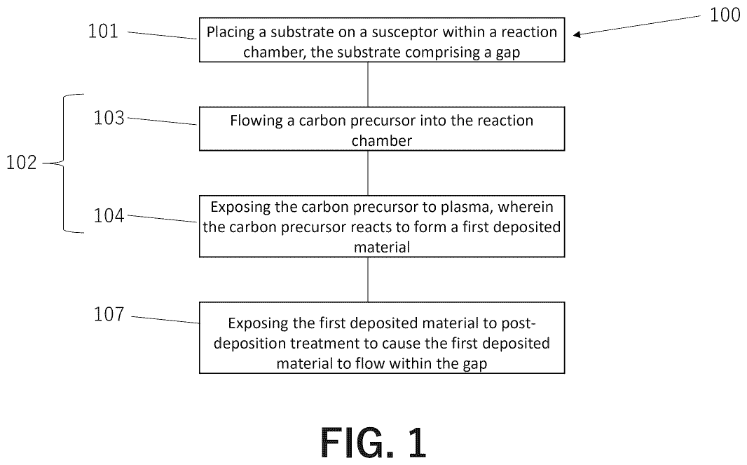

FIG. 1 illustrates a method 100 of filling trenches on a surface of a substrate in accordance with exemplary embodiments of the disclosure. The method 100 may comprise the steps of (a) placing a substrate on a susceptor within a reaction chamber, the substrate comprising a gap (step 101); (b) a deposition step comprising: flowing a carbon precursor into the reaction chamber (step 103); and exposing the carbon precursor to a plasma, wherein the carbon precursor reacts to form a first deposited material (step 104); and (c) a treatment step comprising: exposing the first deposited material to a post-deposition treatment to cause the first deposited material to flow within the gap (step 107).

During step 101 of providing a substrate on a susceptor within a reaction chamber, the substrate may be provided into a reaction chamber of a gas-phase reactor. In accordance with examples of the disclosure, the reaction chamber may form part of a deposition reactor, such as a plasma enhanced chemical vapor deposition (PECVD) reactor. Various steps of methods described herein may be performed (e.g., continuously) within a single reaction chamber or may be performed in multiple reaction chambers, such as reaction chambers on a cluster tool.

During step 101, the substrate may be brought to a desired temperature and/or the reaction chamber may be brought to a desired pressure, such as a temperature and/or pressure suitable for subsequent steps. By way of examples, a temperature (e.g., of a substrate or a substrate support) within a reaction chamber may range between about 30° C. to about 700° C. A pressure within the reaction chamber may be maintained between 1 Pa and 20000 Pa. In accordance with particular examples of the disclosure, the substrate includes one or more features, such as gaps.

During step 103, the carbon precursor may be flowed onto a surface of a substrate. The carbon precursor to fill the gap may be flowed during step 103.

A chemical formula of the carbon precursor comprises: a cyclic compound having a cyclic structure comprising C, H, and N; a carbonyl group; and at least one of a methyl group, an ethyl group, a propyl group, a butyl group, an amine group, and/or a hydroxy group. The cyclic structure may comprise one of pyrrole, furan, thiophene, phosphole, pyrazole, imidazole, oxazole, isoxazole, thiazole, indole, benzofuran, benzothiophene, isoindole, isobenzofurane, benzophosphole, benzimidazole, benzoxazole, benzothiazole, benzoisoxazole, indazole, benzoisothiazole, benzotriazole, purine, pyridine, phosphinine, pyrimidine, pyrazine, pyridazine, triazine, 1,2,4,5-tetrazine, 1,2,3,4,-tetrazine, 1,2,3,5-tetrazine, hexazine, quinoline, isoquinoline, quinoxaline, quinazoline, cinnoline, pteridine, phthalazine, acridine, 4aH-xanthene, 4aH-thioxanthene, 4aH-phenoxazine, 4a, 10a-dihydro-10H-phenothiazine, carbazole, or a combination thereof.

The carbonyl group may comprise one of Aldehyde, Ketone, Carboxylic acid, Ester, Amide, Enone, Acyl chloride, Acid anhydride, or a combination thereof.

During steps 103, one or more inert gases, carrier gas, and dilution gas such as argon, helium, nitrogen, or any mixture thereof, may be provided to the reaction chamber.

During step 104, a plasma may be generated in the reaction chamber by applying a first radio frequency (RF) power to one of one or more electrodes of the reaction chamber. The plasma power ranges for deposition may range from about 10 W to about 3000 W. An RF frequency of the plasma power may range from 400 kHz to 100 MHz. In some embodiments, a second RF power may be applied to one of one or more electrodes of the reaction chamber.

During step 107, the first deposited material may be exposed to a post-deposition treatment to cause the first deposited material to flow within the gap for forming a carbon film. The post-deposition treatment may comprise heating the substrate to a temperature of 200° C. to 800° C. A duration of the post-deposition treatment may be between 1 second and 1,800 seconds.

The post-deposition treatment may comprise annealing a substrate under a temperature of 200° C. to 800° C. A treatment gas (comprising an inert gas and/or an atomic oxygen-containing gas) may be provided to the reaction chamber during the post-deposition treatment. The atomic oxygen-containing gas may comprise one of O₂, O₃, N₂O, NO, NO₂, CO₂, CO, H₂O, CH₃OH, C₂H₅OH, or a combination thereof. The inert gas may comprise at least one of: He, H₂, N₂, He, Ar, or combinations thereof. The inert gas may comprise N₂ and the atomic oxygen-containing gas comprises O₂. The percentage of O₂ may be more than 25% of the treatment gas.

The post-deposition treatment may comprise a plasma treatment. Further, the post-deposition treatment may comprise a UV curing to reduce the time of the treatment. The post-deposition treatment may be conducted in a second reaction chamber.

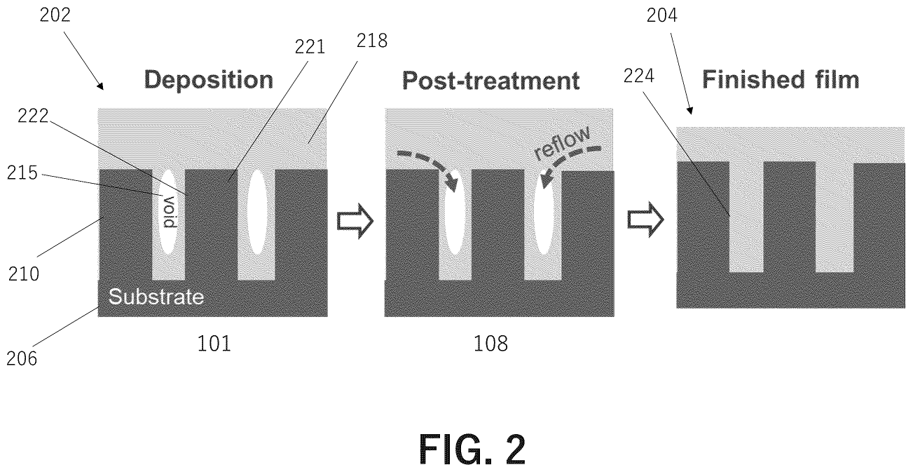

FIG. 2 illustrates a structure formed in accordance with exemplary embodiments of the disclosure. Structure 202 may include a substrate 206 and protrusions 210, 221 formed thereon. Structure 202 includes deposited material 218 overlying substrate 206. As illustrated, deposited material 218 from deposition step 101 includes a void 215 formed within a trench 222 between protrusions 210 and 221. After material 218 is deposited (e.g., enough material to fill the trench 222), deposited material 218 may be exposed to a curing (post-deposition treatment) step to cause deposited material 218 to flow within trench 222 to form structure 204, which includes annealed material 224.

By using the carbon precursor comprising: a cyclic compound having a cyclic structure comprising C, H, and N; a carbonyl group; and at least one of a methyl group, an ethyl group, a propyl group, a butyl group, an amine group, and/or a hydroxy group, the annealed material (carbon film) 224 may exhibit desired characteristics. These characteristics may include a high modulus, low shrinkage, and high etching resistance. An elastic modulus of the annealed material may be more than 7 GPa. A shrinkage may be less than 50%. An etching resistance may improve more than 70% compared with a carbon film formed by an oxygen-containing carbon precursor.

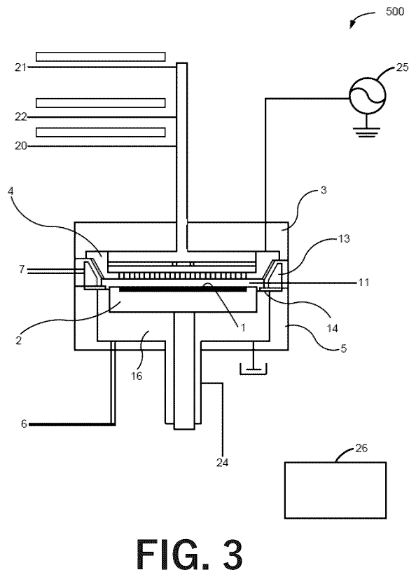

FIG. 3 illustrates a plasma reactor system 500 in accordance with exemplary embodiments of the disclosure is illustrated. The plasma reactor system 500 may be used to perform one or more steps or sub-steps as described herein and/or to form one or more structures or portions thereof as described herein.

The plasma reactor system 500 may include a pair of electrically conductive flat-plate top and bottom electrodes 4, 2 in parallel and facing each other in an interior 11 (reaction zone) of a reaction chamber 3. A plasma may be excited within the reaction chamber 3 by applying, for example, RF power (e.g., 13.56 MHZ, 27 MHz, or 60 MHz) and/or low frequency power from a power source 25 to one electrode (e.g., the top electrode 4) and electrically grounding the other electrode (e.g., the bottom electrode 2). A temperature regulator may be provided in the bottom electrode 2 (serving as a substrate support 2), and a temperature of a substrate 1 placed thereon may be kept at a desired temperature. The top electrode 4 may serve as a gas distribution device, such as a shower plate. Reactant gas, carrier gas, inert gas, dilution gas, if any, precursor gas, and/or the like may be introduced into reaction chamber 3 using one or more of a gas line 20, a gas line 21, and a gas line 22, respectively, and through the shower plate 4. Although illustrated with three gas lines, the reactor system 500 may include any suitable number of gas lines.

In the reaction chamber 3, a circular duct 13 with an exhaust line 7 may be provided, through which gas in the interior 11 of the reaction chamber 3 may be exhausted. Additionally, a transfer chamber 5, disposed below the reaction chamber 3, may be provided with a seal gas line 24 to introduce seal gas into the interior 11 of the reaction chamber 3 via the interior 16 (transfer zone) of the transfer chamber 5, wherein a separation plate 14 for separating the reaction zone and the transfer zone may be provided (a gate valve through which a wafer is transferred into or from the transfer chamber 5 is omitted from this figure). The transfer chamber may be also provided with an exhaust line 6.

A skilled artisan will appreciate that the apparatus includes one or more controller(s) programmed or otherwise configured to cause one or more method steps as described herein to be conducted. The controller(s) are communicated with the various power sources, heating systems, pumps, robotics and gas flow controllers, or valves of the reactor, as will be appreciated by the skilled artisan.

In some embodiments, a dual chamber reactor (two sections or compartments for processing wafers disposed close to each other) may be used, wherein a reactant gas and a noble gas may be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method, comprising the steps of:
(a) placing a substrate on a susceptor within a reaction chamber, the substrate comprising a gap;
(b) a deposition step comprising:
flowing a carbon precursor into the reaction chamber; wherein a chemical formula of the carbon precursor comprises:
a cyclic compound having a cyclic structure comprising C, H, and N;
a carbonyl group; and
at least one of a methyl group, an ethyl group, a propyl group, a butyl group, an amine group, and/or a hydroxy group; and
exposing the carbon precursor to a plasma, wherein the carbon precursor reacts to form a first deposited material; and
(c) a treatment step comprising:
exposing the first deposited material to a post-deposition treatment to cause the first deposited material to flow within the gap for forming a carbon film.

2. The method of claim 1, wherein a temperature during the deposition step is between 30° C. and 700° C.

3. The method of claim 1, further comprising providing an inert gas and/or an atomic oxygen-containing gas during the treatment step.

4. The method of claim 3, wherein the atomic oxygen-containing gas comprises one of O₂, O₃, N₂O, NO, NO₂, CO₂, CO, H₂O, CH₃OH, C₂H₅OH, or a combination thereof.

5. The method of claim 3, wherein the inert gas comprises at least one of: He, H₂, N₂, He, Ar, or combinations thereof.

6. The method of claim 5, wherein the inert gas comprises N₂ and the atomic oxygen-containing gas comprises O₂.

7. The method of claim 6, wherein the ratio of O₂ is more than 25% in total gas.

8. The method of claim 1, wherein a duration of the post-deposition treatment is between 1 second and 1,800 seconds.

9. The method of claim 1, wherein the post-deposition treatment comprises annealing the substrate to a temperature of 200° C. to 800° C.

10. The method of claim 1, wherein the post-deposition treatment comprises a plasma treatment.

11. The method of claim 1, wherein the post-deposition treatment comprises a UV curing.

12. The method of claim 1, wherein the post-deposition treatment is conducted in a second reaction chamber.

13. The method of claim 1, wherein a power of the plasma is between 10 W and 3000 W.

14. The method of claim 1, wherein a frequency of the plasma is between 400 kHz and 100 MHz.

15. The method of claim 1, the cyclic structure comprises one of pyrrole, furan, thiophene, phosphole, pyrazole, imidazole, oxazole, isoxazole, thiazole, indole, benzofuran, benzothiophene, isoindole, isobenzofurane, benzophosphole, benzimidazole, benzoxazole, benzothiazole, benzoisoxazole, indazole, benzoisothiazole, benzotriazole, purine, pyridine, phosphinine, pyrimidine, pyrazine, pyridazine, triazine, 1,2,4,5-tetrazine, 1,2,3,4,-tetrazine, 1,2,3,5-tetrazine, hexazine, quinoline, isoquinoline, quinoxaline, quinazoline, cinnoline, pteridine, phthalazine, acridine, 4aH-xanthene, 4aH-thioxanthene, 4aH-phenoxazine, 4a, 10a-dihydro-10H-phenothiazine, carbazole, or a combination thereof.

16. The method of claim 1, wherein the carbonyl group comprises one of Aldehyde, Ketone, Carboxylic acid, Ester, Amide, Enone, Acyl chloride, Acid anhydride, or a combination thereof.

17. The method of claim 1, wherein one of the electrodes is part of the susceptor.

18. The method of claim 1, wherein an elastic modulus of the carbon film is more than 7 GPa.
